(19) United States
(12) Patent Application Publication
(10) Pub. No.: US 2013/0106266 A1
(43) Pub. Date: May 2, 2013

(54) METHOD FOR MAKING DEVICE HOUSING AND DEVICE HOUSING MADE BY SAME

(71) Applicants: DA-HUA CAO, Shenzhen City (CN); XU LIU, Shenzhen City (CN)

(72) Inventors: DA-HUA CAO, Shenzhen City (CN); XU LIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/433,307

(22) Filed: Mar. 29, 2012

(30) Foreign Application Priority Data
Oct. 31, 2011 (CN) 201110337331.0

(51) Int. Cl. C23C 14/16; C23C 14/35; C23C 16/56; A47B 96/00; C23C 16/06

(52) U.S. Cl. 312/237; 427/556; 204/192.15

(57) ABSTRACT

A method for making a device housing includes providing a metal substrate; forming a first metallic coating on a surface of the metal substrate by physical vapor deposition; forming an ink layer entirely covering the first metallic coating; laser engraving the ink layer to remove portions of the ink layer to form openings; forming a second metallic coating by physical vapor deposition, the second metallic coating covering the ink layer and filling the openings, the second metallic coating and the first metallic coating having different colors; and removing the ink layer and portions of the second metallic coating covering the ink layer by cleaning with an organic solution.

### BACKGROUND

1. Technical Field

The present disclosure relates to a method for making a device housing and a device housing made by the method.

2. Description of Related Art

Metallic films formed by physical vapor deposition (PVD) are attractive. A typical method for making a dual-color pattern on a device housing by PVD includes forming a first color film on the device housing. An ink layer having openings is then screen printed on the first color film. The openings cooperatively form a predetermined pattern. A second color film is formed covering the first color film and the openings. The ink layer with portions of the second color film formed thereon is removed, leaving portions of the first color film forming a pattern. However, the ink layer formed by screen printing usually has sawtooth cracks in the peripheries of the openings. So, it is difficult to achieve a precious pattern on a three-dimensional surface by such method.

Therefore, there is room for improvement within the art.

### BRIEF DESCRIPTION OF THE DRAWINGS

Many aspects of the present disclosure can be better understood with reference to the drawings. The components in the drawings are not necessarily drawn to scale, the emphasis instead being placed upon clearly illustrating the principles of the disclosure. Moreover, in the drawings like reference numerals designate corresponding parts throughout the views.

FIG. 1 is a schematic view showing a manufacturing process of forming a first metallic coating in the method of making a device housing according to an exemplary embodiment.

FIG. 2 is a schematic view showing a manufacturing process of forming an ink layer in the method of making a device housing according to an exemplary embodiment.

FIG. 3 is a schematic view showing a manufacturing process of laser engraving the ink layer to form a pattern in the method of making a device housing according to an exemplary embodiment.

FIG. 4 is a schematic view showing a manufacturing process of forming a second metallic coating in the method of making a device housing according to an exemplary embodiment.

FIG. 5 is a cross-section view of a device housing made by the present method according to an exemplary embodiment.

### DETAILED DESCRIPTION

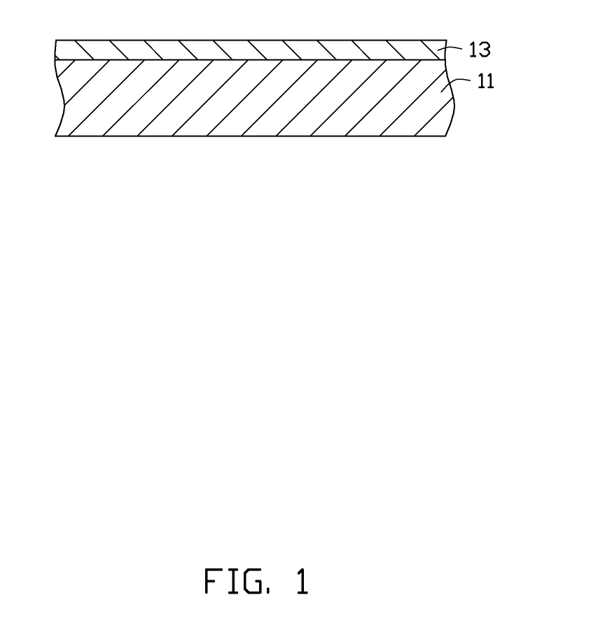

Referring to FIGS. 1-4, an exemplary method for making a device housing may include the following steps.

A metal substrate 11 is provided. The metal substrate 11 may be made of stainless steel, aluminum alloy, zinc, or copper.

The metal substrate 11 may be degreased, removing oil stains on the metal substrate 11.

Referring to FIG. 1, a first metallic coating 13 having a first color may be formed on a surface of the metal substrate 11 by physical vapor deposition, such as vacuum evaporation or magnetron sputtering. In the exemplary embodiment, the first metallic coating 13 is formed by magnetron sputtering titanium targets or chromium targets using acetylene as reacting gas. During the magnetron sputtering, about 8 kW-about 10 kW of power is applied to titanium targets or chromium targets. The magnetron sputtering may take about 20 minutes to about 30 minutes. The first metallic coating 13 may be titanium carbide or chromium carbide. The first metallic coating 13 may have a thickness of about 0.5 μm-about 1.0 μm.

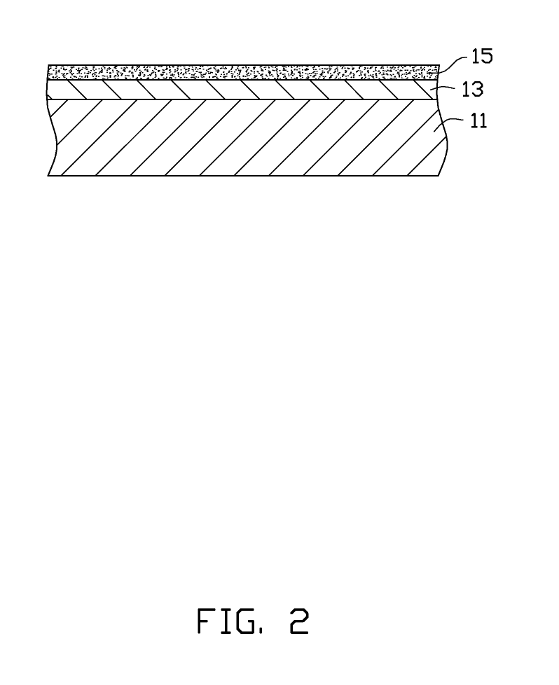

Referring to FIG. 2, an ink layer 15 is formed on the first metallic coating 13, entirely covering the first metallic coating 13. The ink layer 15 may be formed by spraying, for example. The ink layer 15 may be formed of an ink resistant to high temperature. The ink layer 15 may be dried at a temperature of about 60° C.-about 70° C. for about 1 hour. The ink layer 15 may have a thickness of about 3 μm-about 5 μm.

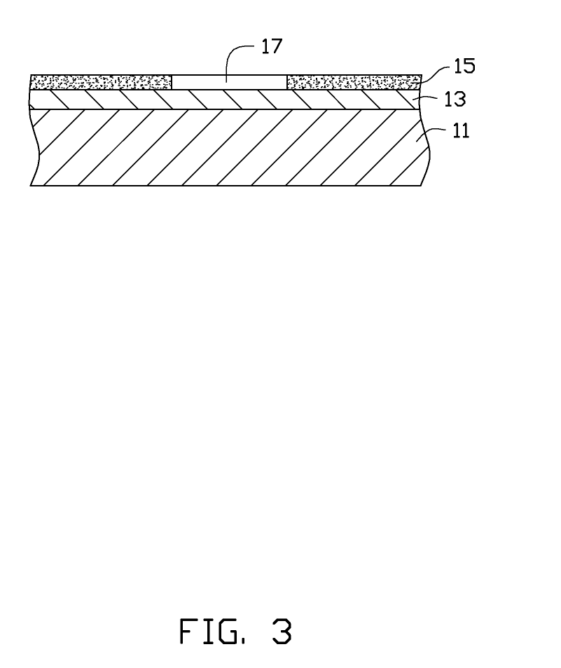

Referring to FIG. 3, the ink layer 15 may be laser engraved, removing portions of the ink layer 15 to form openings 17. The openings cooperatively 17 depict a desired symbol, logo, or pattern. Portions of the first metallic coating 13 are exposed out of the ink layer 15 via the openings 17. The openings 17 formed by laser engraving have flush peripheries, ensuring a precious pattern is subsequently formed.

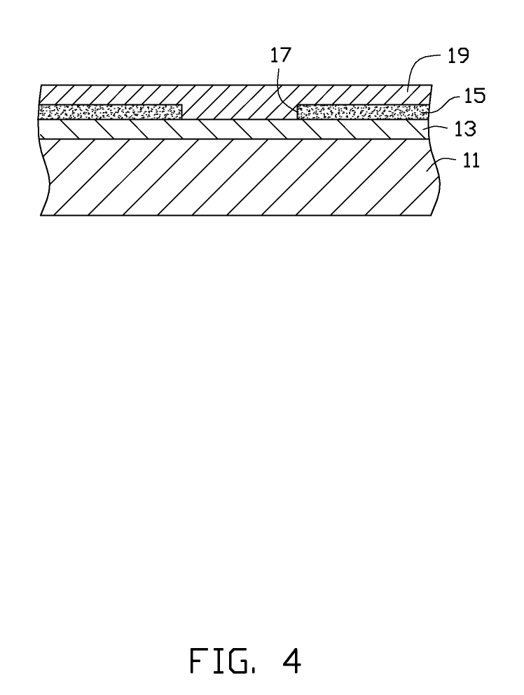

Referring to FIG. 4, a second metallic coating 19 may be formed on the ink layer 15 by physical vapor deposition, such as vacuum evaporation or magnetron sputtering. The second metallic coating 19 covers the ink layer 15 and fills the openings 17. The second metallic coating 19 has a second color different from that of the first metallic coating 13. In the embodiment, the second metallic coating 19 is formed by magnetron sputtering titanium targets or chromium targets using nitrogen as reacting gas. During the magnetron sputtering, about 8 kW-about 10 kW of power is applied to titanium targets or chromium targets. The magnetron sputtering may take about 20 minutes to about 30 minutes. The second metallic coating 19 may be titanium nitride or chromium nitride. The second metallic coating 19 may have a thickness of about 0.5 μm-about 1.0 μm.

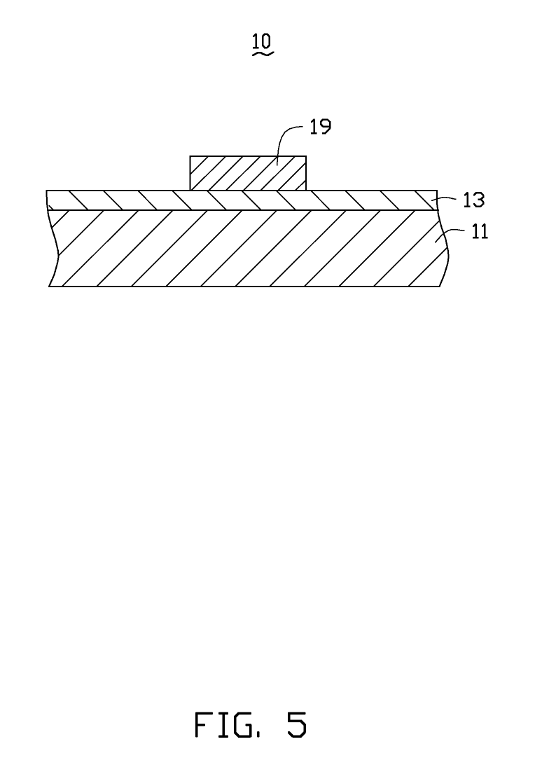

Referring to FIG. 5, the ink layer 15 with portions of the second metallic coating 19 formed thereon may be removed by cleaning with an organic solution. The organic solution may only dissolve the ink layer 15 and have no effect with the first metallic coating 13 and the second metallic coating 19. Portions of the second metallic coating 19 filling in the openings 17 remain and depict a desired pattern.

FIG. 5 shows an exemplary device housing 10 made by the present method. The device housing 10 includes the metal substrate 11 having the first metallic coating 13 and the second metallic coating 19 formed thereon, and in that order. The second metallic coating 19 covers portions of the first metallic coating 13 and depict a desired pattern thereon. The second metallic coating 19 and the first metallic coating 13 have different colors. The first metallic coating 13 may be titanium carbide or chromium carbide. The second metallic coating 19 may be titanium nitride or chromium nitride.

However, even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for making a device housing, comprising:
providing a metal substrate;
forming a first metallic coating on a surface of the metal substrate by physical vapor deposition;
forming an ink layer entirely covering the first metallic coating;
laser engraving the ink layer to remove portions of the ink layer to form openings;
forming a second metallic coating by physical vapor deposition, the second metallic coating covering the ink layer and filling the openings, the second metallic coating and the first metallic coating having different colors; and
removing the ink layer and portions of the second metallic coating covering the ink layer by cleaning with an organic solution.

2. The method as claimed in claim 1, wherein the first metallic coating is formed by magnetron sputtering titanium targets or chromium targets using acetylene as reacting gas.

3. The method as claimed in claim 2, wherein during the magnetron sputtering, about 8 kW-10 kW of power is applied to titanium targets or chromium targets.

4. The method as claimed in claim 3, wherein the magnetron sputtering takes about 20 minutes to about 30 minutes.

5. The method as claimed in claim 1, wherein the ink layer is formed by spraying.

6. The method as claimed in claim 1, wherein the second metallic coating is formed by magnetron sputtering titanium targets or chromium targets using nitrogen as reacting gas.

7. A device housing, comprising:
a metal substrate;
a first metallic coating formed on a surface of the metal substrate; and
a second metallic coating covering portions of the first metallic coating and depicting a desired pattern, the second metallic coating and the first metallic coating having different colors.

8. The device housing as claimed in claim 7, wherein the first metallic coating is formed of titanium carbide or chromium carbide.

9. The device housing as claimed in claim 7, wherein the second metallic coating is formed of titanium nitride or chromium nitride.
